(19) United States
(12) Patent Application Publication
(10) Pub. No.: US 2024/0103366 A1
(43) Pub. Date: Mar. 28, 2024

(54) PHOTOSENSITIVE RESIN COMPOSITION, PHOTOSENSITIVE RESIN LAYER USING THE SAME, AND COLOR FILTER

(71) Applicant: SAMSUNG SDI CO., LTD., Yougin-si (KR)

(72) Inventors: Jihong KIM, Suwon-si (KR); Young-Tai LEE, Suwon-si (KR); Sangho LEE, Suwon-si (KR); Sabina KIM, Suwon-si (KR); Kwangseop KIM, Suwon-si (KR); Jeongho YOO, Suwon-si (KR); Jihye KIM, Suwon-si (KR); Ieju KIM, Suwon-si (KR); Ickjin KIM, Suwon-si (KR); Myungho CHO, Suwon-si (KR); Baek Soung PARK, Suwon-si (KR)

(21) Appl. No.: 18/244,370

(22) Filed: Sep. 11, 2023

(30) Foreign Application Priority Data
Sep. 15, 2022 (KR) 10-2022-0116659

(51) Int. Cl. G03F 7/004; G02B 1/04; G03F 7/00

(52) U.S. Cl. CPC G03F 7/0048; G02B 1/04; G03F 7/0007; G02B 5/20

(57) ABSTRACT

A photosensitive resin composition includes an additive; a binder resin; a photopolymerizable compound; a photopolymerization initiator; a colorant; and a solvent, wherein the additive includes a leveling agent, and the leveling agent is included in an amount of about 15 ppm to about 30 ppm, based on a total amount of the photosensitive resin composition.

### CROSS-REFERENCE TO RELATED APPLICATION

This application claims priority to and the benefit of Korean Patent Application No. 10-2022-0116659 filed in the Korean Intellectual Property Office on Sep. 15, 2022, the entire contents of which are incorporated herein by reference.

### BACKGROUND

### 1. Field

Embodiments relate to a photosensitive resin composition, a photosensitive resin layer manufactured using the photosensitive resin composition, and a color filter.

### 2. Description of the Related Art

An image sensor is a semiconductor that converts photons into electrons and displays them on a display device or stores them in a storage device.

The image sensor may be, e.g., a charge coupled device (CCD) image sensor or a complementary metal-oxide semiconductor (CMOS) image sensor according to a manufacturing process and an application method.

The complementary metal-oxide semiconductor (CMOS) image sensor (CIS), which is a non-memory semiconductor that converts an image received by a camera to a digital signal, is a collection of pixels such as a color filter, a photodiode, an amplifier, and the like as.

The color filter includes filter segments of additively blended primary colors of red, green, and blue. The color filter may be manufactured by repeating a series of processes such as coating a photosensitive resin composition containing a colorant on a substrate, exposing a pattern to be formed, developing it, and thermally curing it through a post-bake process to form a photosensitive resin layer.

### SUMMARY

The embodiments may be realized by providing a photosensitive resin composition including an additive; a binder resin; a photopolymerizable compound; a photopolymerization initiator; a colorant; and a solvent, wherein the additive includes a leveling agent, and the leveling agent is included in an amount of about 15 ppm to about 30 ppm, based on a total amount of the photosensitive resin composition.

The leveling agent may be included in an amount of about 20 ppm to about 25 ppm, based on the total amount of the photosensitive resin composition.

The leveling agent may be a fluorine surfactant.

The fluorine surfactant may be a non-ionic fluorine surfactant.

The additive may further include a dispersion medium.

The leveling agent may be included in an amount of about 1 wt % to about 20 wt %, based on a total weight of the additive.

A weight ratio of the leveling agent and the colorant may be about 1:700 to about 1:900.

The additive may further include malonic acid; 3-amino-1,2-propanediol; a coupling agent that includes a vinyl group or a (meth)acryloxy group; or a radical polymerization initiator.

The binder resin may include an acrylic binder resin, an epoxy binder resin, or a combination thereof.

The colorant may include a blue pigment, a violet pigment, or a combination thereof.

The solvent may include two or more solvents having different boiling points.

The solvent may include two or more of propylene glycol monomethyl ether acetate (PGMEA), n-butyl alcohol (n-BA), and diethylene glycol methyl ethyl ether (MED G).

The photosensitive resin composition may include about 15 ppm to about 30 ppm of the additive; about 1 wt % to about 20 wt % of the binder resin; about 1 wt % to about 20 wt % of the photopolymerizable compound; about 0.1 wt % to about 5 wt % of the photopolymerization initiator; about 5 wt % to about 70 wt % of the colorant; and the solvent, all amounts being based on a total weight of the photosensitive resin composition.

The photosensitive resin composition may have a viscosity of about 1.5 cP to about 3.8 cP at 25° C.

The embodiments may be realized by providing a photosensitive resin layer manufactured using the photosensitive resin composition according to an embodiment.

The embodiments may be realized by providing a color filter including a photosensitive resin layer according to an embodiment.

The embodiments may be realized by providing a CMOS image sensor comprising the color filter according to an embodiment.

### BRIEF DESCRIPTION OF THE DRAWINGS

Features will be apparent to those of skill in the art by describing in detail exemplary embodiments with reference to the attached drawings in which:

FIG. 1 schematically illustrates an exposure pattern according to evaluation examples.

FIG. 2 illustrates a thickness profile according to an evaluation example.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that if a layer or element is referred to as being “on” another layer or element, it can be directly on the other layer or element, or intervening layers may also be present. Further, it will be understood that if a layer is referred to as being “under” another layer, it can be directly under, and one or more intervening layers may also be present. In addition, it will also be understood that if a layer is referred to as being “between” two layers, it can be the only layer between the two layers, or one or more intervening layers may also be present. As used herein, the term “or” is not necessarily an exclusive term, e.g., “A or B” would include A, B, or A and B.

As used herein, if specific definition is not otherwise provided, “substituted” refers to replacement of at least one hydrogen of a compound by a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, or a combination thereof.

As used herein, if specific definition is not otherwise provided, “heterocycloalkyl group”, “heterocycloalkenyl group”, “heterocycloalkynyl group,” and “heterocycloalkylene group” refer to presence of at least one N, O, S, or P in a cyclic compound of cycloalkyl, cycloalkenyl, cycloalkynyl, and cycloalkylene.

As used herein, if specific definition is not otherwise provided, “(meth)acrylate” refers to both “acrylate” and “methacrylate”.

In the chemical formulae of the present specification, unless a specific definition is otherwise provided, hydrogen is boned at the position if a chemical bond is not drawn where supposed to be given.

As used herein, if a definition is not otherwise provided, “*” refers to a linking part between the same or different atoms, or Chemical Formulae.

As used herein, “particle size” or “particle diameter” is defined as the particle size in a particle size distribution standard. For example, the particle size or particle diameter “Dn” means the particle size if particles distributed in various particle sizes are accumulated up to “n %” in volume ratio. For example, D50 means the particle size if particles are accumulated up to 50% by volume.

The particle size or particle diameter “Dn” can be measured by methods well known to those skilled in the art, for example, by particle size analyzer, or by transmission electron micrograph or scanning electron micrograph. Alternatively, it may be measured using a dynamic light scattering method and then subjected to data analysis.

(Photosensitive Resin Composition)

Embodiments provide a photosensitive resin composition including, e.g., (A) an additive; (B) a binder resin; (C) a photopolymerizable compound; (D) a photopolymerization initiator; (E) a colorant; and (F) a solvent. In an implementation, the additive may include a leveling agent, and the leveling agent may be included in an amount of about 15 ppm to about 30 ppm (e.g., by weight), based on a total amount (e.g., weight) of the photosensitive resin composition.

(A) Additive

In an implementation, the additive may include a leveling agent.

Herein, the “leveling agent” may be an additive improving fluidity of the photosensitive resin composition by adjusting an evaporation rate of the solvent or preventing aggregation of the colorant.

If a coating thickness distribution were to occur during the process of coating the photosensitive resin composition on the substrate or the lower photosensitive resin layer, a rough surface could be physically formed during the following process of forming a pattern (exposure, development).

If the photosensitive resin composition were to be coated on the lower photosensitive resin layer, which has already been formed, the leveling agent in the photosensitive resin composition could cause severe obstacles at a barrier rib depending on an amount of the leveling agent and thus could generate variations in a coating thickness. If the photosensitive resin composition were to be coated in a spin-coating method, the coating thickness could be non-uniform at the edge portion of the substrate or the lower photosensitive resin layer, compared with the center portion due to limitations of the coating method.

If exposed in such a state with the variations in the coating thickness, a deteriorated pattern could be formed, and a color filter with low surface smoothness could be inevitably obtained.

A leveling agent may help to uniformly coat the photosensitive resin composition on the substrate or the lower photosensitive resin layer. Coating uniformity of the photosensitive resin composition could vary depending on a content of the leveling agent.

According to an embodiment, the content of the leveling agent may be optimized to secure the coating uniformity the photosensitive resin composition on the substrate or the lower photosensitive resin layer. Accordingly, a photosensitive resin layer and a color filter formed by using the photosensitive resin composition according to some embodiments may exhibit excellent surface smoothness and contribute to realizing an image sensor with image quality at a predetermined level.

In an implementation, the leveling agent may only be a material in a solid state, which may be included in an amount of about 15 ppm to about 30 ppm, based on a total amount of the photosensitive resin composition.

If the content of the leveling agent were to be less than the lower limit, the effect of the leveling agent may be insignificant. If the content of the leveling agent were to exceed the upper limit, flatness could be rather inferior.

Within the above range, the higher the content of the leveling agent, the more uniformly coated the photosensitive resin composition. In an implementation, the leveling agent may be included in an amount of about 15 ppm to about 30 ppm, about 15 ppm to about 25 ppm, or about 20 ppm to about 25 ppm, based on a total amount of the photosensitive resin composition.

In an implementation, the leveling agent may include, e.g., a fluorine surfactant.

The fluorine surfactant may be prepared by a substitution reaction of a water-soluble reactive group at the terminal end of a hydrophobic linear molecule containing a fluorine atom, and may have better surface tension resistance than other surfactants.

Surfactants may be classified into ionic surfactants and nonionic surfactants depending on whether the hydrophilic moiety is ionic, and the fluorine surfactant may be a nonionic fluorine surfactant in which a hydrophilic moiety is not ionic

In an implementation, the non-ionic fluorine surfactant may include F-554, F-556, F-553, F-559, and the like of DIC Co., Ltd.

The additive may further include a dispersion medium in addition to the leveling agent. In this case, the leveling agent may be dispersed in the dispersion medium and used in the form of a leveling agent dilution or dispersion. The dispersion medium may include a solvent described below.

In the additive further including the dispersion medium, the leveling agent may be included in an amount of about 1 wt % to about 20 wt %, based on a total weight of the additive. In an implementation, the leveling agent dilution concentration in the leveling agent dilution may be about 1 wt % to about 20 wt %.

Within this range, the leveling agent may be uniformly dispersed in the photosensitive resin composition, and furthermore, surface smoothness of the photosensitive resin layer and color filter manufactured using the photosensitive resin composition may be increased.

In an implementation, in the additive further including the dispersion medium, the leveling agent may be included in an amount of about 1 wt % to about 20 wt %, about 5 wt % to about 15 wt %, or about 7 wt % to about 12 wt %.

In an implementation, the colorant as well as the leveling agent may be a material in a solid state alone, and a weight ratio of the leveling agent and the colorant may be about 1:700 to about 1:900.

Within this range, a content of the leveling agent relative to the colorant may be appropriately controlled, so that the photosensitive resin composition may be uniformly coated on the substrate or the lower photosensitive resin layer. As the content of the leveling agent compared to the colorant in the above range increases, the uniformity may increase, and if the content decreases, the uniformity may also decrease.

Considering this trade-off relationship, the weight ratio of the leveling agent and the colorant may be about 1:700 to about 1:900, about 1:700 to about 1:850, or about 1:750 to about 1:800.

The photosensitive resin composition may further include another additive, e.g., malonic acid; 3-amino-1,2-propanediol; a coupling agent containing a vinyl group or a (meth)acryloxy group; or a radical polymerization initiator, in order to help prevent stains or spots during the coating, to help improve leveling performance, or to help prevent the generation of undeveloped residues.

The other additives may be adjusted according to desired physical properties.

The coupling agent may be a silane coupling agent, and examples of the silane coupling agent may include trimethoxysilyl benzoic acid, y methacryl oxypropyl trimethoxysilane, vinyl triacetoxysilane, vinyl trimethoxysilane, y isocyanate propyl triethoxysilane, y glycidoxy propyl trimethoxysilane, and R epoxycyclohexyl) ethyltrimethoxysilane, which can be used alone or in mixture of 2 or more types.

The silane coupling agent may be used in an amount of about 0.01 part by weight to about 1 part by weight, based on 100 parts by weight of the photosensitive resin composition.

In an implementation, a certain amount of other additives such as an antioxidant, a stabilizer, or the like may be added to the photosensitive resin composition within a range that does not impair physical properties.

The additives further included may be included in an amount of about 0.01 wt % to about 5 wt % or in an amount of about 0.01 wt % to about 2 wt % based on a total weight of the photosensitive resin composition. If it were to be out of the above range, foreign substances or byproducts could be generated after development.

(B) Binder Resin

The photosensitive resin composition may include a binder resin. In an implementation, the binder resin may include an acrylic binder resin.

The acrylic resin may be a copolymer of a first ethylenic unsaturated monomer and a second ethylenic unsaturated monomer that is copolymerizable therewith, and may be a resin including at least one acryl repeating unit.

The first ethylenic unsaturated monomer may be an ethylenic unsaturated monomer including at least one carboxyl group. Examples of the monomer may include acrylic acid, methacrylic acid, maleic acid, itaconic acid, fumaric acid, and a combination thereof.

The first ethylenic unsaturated monomer may be included in an amount of about 5 wt % to about 50 wt %, e.g., about 10 wt % to about 40 wt %, based on a total weight of the acrylic binder resin.

The second ethylenic unsaturated monomer may be an aromatic vinyl compound such as styrene, α-methylstyrene, vinyl toluene, vinylbenzylmethylether, or the like; an unsaturated carboxylate ester compound such as methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, or the like; an unsaturated amino alkyl carboxylate ester compound such as 2-aminoethyl(meth)acrylate, 2-dimethylaminoethyl(meth)acrylate, or the like; a carboxylic acid vinyl ester compound such as vinyl acetate, vinyl benzoate, or the like; an unsaturated glycidyl carboxylate ester compound such as glycidyl(meth)acrylate, or the like; a vinyl cyanide compound such as (meth)acrylonitrile or the like; an unsaturated amide compound such as (meth)acrylamide, or the like; or the like, and may be used alone or as a mixture of two or more.

Examples of the acrylic resin may include a (meth)acrylic acid/benzylmethacrylate copolymer, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, and these may be used alone or as a mixture of two or more.

In an implementation, the binder resin may include an epoxy binder resin.

The binder resin may help improve heat resistance by further including an epoxy binder resin. The epoxy binder resin may include, e.g., a phenol novolac epoxy resin, a tetramethyl biphenyl epoxy resin, a bisphenol A epoxy resin, a bisphenol F epoxy resin, an alicyclic epoxy resin, or a combination thereof.

In an implementation, the binder resin including the epoxy binder resin may help secure dispersion stability of a colorant such as a pigment, which will be described below, and may help to form a pixel having a desired resolution during a developing process.

The epoxy binder resin may be included in an amount of about 1 wt % to about 10 wt %, e.g., about 5 wt % to about 10 wt %, based on a total weight of the binder resin. If the epoxy binder resin is included in the above range, film residue ratio and chemical resistance may be greatly improved.

An epoxy equivalent weight of the epoxy resin may be about 150 g/eq to about 200 g/eq. If an epoxy binder resin having an epoxy equivalent within the above range is included in the binder resin, there may be an advantageous effect in improving a curing degree of the formed pattern and fixing the colorant in the structure in which the pattern is formed.

The binder resin may be dissolved in a solvent to be described below in a solid form to form a photosensitive resin composition. In this case, the binder resin in the solid form may be about 10 wt % to about 50 wt %, e.g., about 20 wt % to about 40 wt %, based on a total weight of the binder resin solution dissolved in the solvent.

The binder resin may be included in an amount of about 1 wt % to about 20 wt %, e.g., about 1 wt % to about 15 wt %, or about 1 wt % to about 10 wt %, based on a total weight of the photosensitive resin composition. If the binder resin is included within the above range, it is possible to obtain excellent surface smoothness due to excellent developability and improved crosslinking property during manufacture of the color filter.

(C) Photopolymerizable Compound

The photopolymerizable compound may additionally include a monofunctional or multifunctional ester of (meth)acrylic acid having at least one ethylenic unsaturated double bond.

The photopolymerizable compound has the ethylenic unsaturated double bond, so that it may form a pattern having excellent heat resistance, light resistance, and chemical resistance by causing sufficient polymerization during exposure in the pattern forming process.

Examples of the photopolymerizable compound may include ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, and the like.

Examples of commercially available products of the photopolymerizable compound may be as follows. The mono-functional (meth)acrylic acid ester may include Aronix M-101 ®, Aronix M-111 ®, Aronix M-114 ® (Toagosei Chemistry Industry Co., Ltd.); KAYARAD TC-110S®, KAYARAD TC-120S® (Nippon Kayaku Co., Ltd.); V-158 ®, V-2311 (Osaka Organic Chemical Ind., Ltd.), and the like. Examples of a difunctional (meth)acrylic acid ester may include Aronix M-210 ®, Aronix M-240 ®, Aronix M-6200 ® (Toagosei Chemistry Industry Co., Ltd.), KAYARAD HDDA®, KAYARAD HX-220 ®, KAYARAD R-604 ® (Nippon Kayaku Co., Ltd.), V-260 ®, V-312 ®, V-335 HP® (Osaka Organic Chemical Ind., Ltd.), and the like. Examples of a tri-functional (meth)acrylic acid ester may include Aronix M-309 ®, Aronix M-400 ®, Aronix M-405 ®, Aronix M-450 ®, Aronix M-710 ®, Aronix M-8030 ®, Aronix M-8060 ® (Toagosei Chemistry Industry Co., Ltd.); KAYARAD TMPTA®, KAYARAD DPCA-20 ®, KAYARAD DPCA-30 ®, KAYARAD DPCA-60 ®, KAYARAD DPCA-120 ® (Nippon Kayaku Co., Ltd.); V-295 ®, V-300 ®, V-360 ®, V-GPT®, V-3PA®, V-400 ® (Osaka Yuki Kayaku Kogyo Co. Ltd.), and the like. These may be used alone or as a mixture of two or more.

The photopolymerizable compound may be treated with an acid anhydride or may be modified ethylene oxide to impart better developability.

The added photopolymerizable compound may be included in an amount of about 1 wt % to about 20 wt %, e.g., about 1 wt % to about 4 wt %, or about 1 wt % to about 3 wt %, based on a total weight of the photosensitive resin composition. If the photopolymerizable compound is included within the above range, sufficient curing may occur during exposure in the pattern forming process, resulting in excellent reliability and excellent developability with an alkali developing solution.

(D) Photopolymerization Initiator

The photopolymerization initiator may be an initiator suitably used in a photosensitive resin composition, e.g., an acetophenone compound, a benzophenone compound, a thioxanthone compound, a benzoin compound, a triazine compound, an oxime compound, or a combination thereof.

Examples of the acetophenone compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone compound may include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone compound may include thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin compound may include benzoin, benzoin methyl ether, benzoin ethyl ether, benzoin isopropyl ether, benzoin isobutyl ether, benzyldimethylketal, and the like.

Examples of the triazine compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compound may include O-acyloxime-based compound, 2-(o-benzoyloxime)-1-[4-(phenylthio)phenyl]-1,2-octandione, 1-(o-acetyloxime)-1-[9-ethyl-6-(2-methylbenzoyl)-9H-carbazol-3-yl]ethanone, 0-ethoxycarbonyl-a-oxyamino-1-phenylpropan-1-one, and the like. Specific examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

In an implementation, the photopolymerization initiator may further include a carbazole compound, a diketone compound, a sulfonium borate compound, a diazo compound, an imidazole compound, a biimidazole compound, a fluorene compound, or the like, in addition to the other compounds.

The photopolymerization initiator may be used with a photosensitizer capable of causing a chemical reaction by absorbing light and becoming excited and then, transferring its energy.

Examples of the photosensitizer may include tetraethylene glycol bis-3-mercapto propionate, pentaerythritol tetrakis-3-mercapto propionate, dipentaerythritol tetrakis-3-mercapto propionate, and the like.

The photopolymerization initiator may be included in an amount of about 0.1 wt % to about 5 wt %, e.g., about 0.3 wt % to about 4 wt %, or about 0.5 wt % to about 3 wt %, based on a total weight of the photosensitive resin composition. If the photopolymerization initiator is included within the ranges, sufficient photopolymerization may occur during exposure in a pattern-forming process, excellent reliability may be realized, heat resistance, light resistance, and chemical resistance of patterns, resolution and close contacting properties may be improved, and decrease of transmittance due to a non-reaction initiator may be prevented.

(E) Colorant

The photosensitive resin composition of some embodiments may include a pigment as a colorant.

The pigment may include a red pigment, a violet pigment, a green pigment, a blue pigment, a yellow pigment, a black pigment, or the like.

The red pigment may include C.I. Red Pigment 254, C.I. Red Pigment 255, C.I. Red Pigment 264, C.I. Red Pigment 270, C.I. Red Pigment 272, C.I. Red Pigment 177, C.I. Red Pigment 89, or the like in the color index, which may be used alone or in a mixture of two or more.

The violet pigment may include C.I. Violet Pigment 23 (V.23), C.I. Violet Pigment 29, Dioxazine Violet, First Violet B, Methyl Violet Lake, Indanethrene Brilliant Violet, or the like in the color index, which may be used alone or in a mixture of two or more.

The green pigment may include C.I. Green Pigment 7, C.I. Green Pigment 36, C.I. Green Pigment 58, C.I. Green Pigment 59, or the like in the color index, which may be used alone or in a mixture of two or more.

The blue pigment may include copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 15:6, or C.I. Blue Pigment 16 in the color index, which may be used alone or in a mixture of two or more.

The yellow pigment may include an isoindoline pigment such as C.I. Yellow Pigment 185, C.I. Yellow Pigment 139, or the like, a quinophthalone pigment such as C.I. Yellow Pigment 138, or a nickel complex pigment such as C.I. Yellow Pigment 150 in the color index, which may be used alone or in a mixture of two or more.

The black pigment may include aniline black, perylene black, titanium black, carbon black, or the like in the color index, which may be used alone or in a mixture of two or more.

In an implementation, the colorant may implement a blue color by including a blue pigment, a purple pigment, or a combination thereof. In an implementation, the pigment may be a mixture including a blue pigment and a violet pigment in a weight ratio of about 95:5 to about 60:40, about 90:10 to about 70:30, or about 85:15 to about 75:25.

The pigment may be included in a near-infrared absorbing resin composition in the form of a dispersion. Such a pigment dispersion may include the pigment, a solvent, a dispersant, a dispersion resin, or the like.

The solvent may include, e.g., ethylene glycol acetate, ethyl cellosolve, propylene glycol methyl ether acetate, ethyl lactate, polyethylene glycol, cyclohexanone, propylene glycol methyl ether, or the like. In an implementation, the solvent may include propylene glycol methyl ether acetate.

The dispersant may help to uniformly disperse the pigment in the dispersion, and both of a nonionic, anionic, or cationic dispersant may be used. In an implementation, polyalkylene glycol or esters thereof, polyoxyalkylene, a polyhydric alcohol ester alkylene oxide adduct, an alcohol alkylene oxide adduct, a sulfonic acid ester, a sulfonic acid salt, a carboxylic acid ester, a carboxylic acid salt, an alkyl amide alkylene oxide adduct, alkyl amine, or the like may be used, and these may be used alone or in a mixture of two or more.

The dispersion resin may include an acrylic resin containing a carboxy group may be used, which may help improve stability of the pigment dispersion and also help improve pixel patternability.

The colorant may further include a dye while also including the pigment, and in this case, the resin composition of some embodiments may be a hybrid composition. In an implementation, the dye may include a metal complex dye.

The metal complex dye may be a compound having maximum absorbance in the wavelength range of about 200 nm to about 650 nm. If the compound has absorbance in the above range in order to match the color coordinates to the combination of dyes, the metal complex dye of all colors that dissolves in an organic solvent may be used.

In an implementation, the metal complex dye may be a green dye having maximum absorbance in a wavelength range of about 530 nm to about 680 nm, a yellow dye having maximum absorbance in a wavelength range of about 200 nm to about 400 nm, an orange dye having a maximum absorbance in a wavelength range of about 300 nm to about 500 nm, a red dye having maximum absorbance in a wavelength range of about 500 nm to about 650 nm, or a combination thereof.

The metal complex dye may be a direct dye, an acidic dye, a basic dye, an acidic mordant dye, a sulfide dye, a reduction dye, an azoic dye, a dispersion dye, a reactive dye, an oxidation dye, an oil-soluble dye, an azo dye, an anthraquinone dye, an indigoid dye, a carbonium ion dye, a phthalocyanine dye, a nitro dye, a quinoline dye, a cyanine dye, a polymethine dye, or a combination thereof.

The metal complex dye may include Mg, Ni, Cu, Co, Zn, Cr, Pt, Pd, or Fe.

In an implementation, the metal complex dye may be a complex of, e.g., C.I. Solvent Dye such as C.I. Solvent Green 1, 3, 4, 5, 7, 28, 29, 32, 33, 34, 35, or the like; C.I. Acid Dye such as C.I. Acid Green 1, 3, 5, 6, 7, 8, 9, 11, 13, 14, 15, 16, 22, 25, 27, 28, 41, 50, 50:1, 58, 63, 65, 80, 104, 105, 106, 109, or the like; C.I. Direct Dye such as C.I. Direct Green 25, 27, 31, 32, 34, 37, 63, 65, 66, 67, 68, 69, 72, 77, 79, 82, or the like; C.I. Basic Dye such as C.I. Basic Green 1, or the like; C.I. Mordant Dye such as C.I. Mordant Green 1, 3, 4, 5, 10, 13, 15, 19, 21, 23, 26, 29, 31, 33, 34, 35, 41, 43, 53, or the like; C.I. Green pigments such as Pigment Green 7, 36, 58, or the like; Solvent Yellow 19, Solvent Yellow 21, Solvent Yellow 25, Solvent Yellow 79, Solvent Yellow 82, Solvent Yellow 88, Solvent Orange 45, Solvent Orange 54, Solvent Orange 62, Solvent Orange 99, Solvent Red 8, Solvent Red 32, Solvent Red 109, Solvent Red 112, Solvent Red 119, Solvent Red 124, Solvent Red 160, Solvent Red 132, or Solvent Red 218, and the metal ion.

The metal complex dye may have a solubility of greater than or equal to about 5, e.g., about 5 to about 10, in a solvent used in the photosensitive resin composition according to some embodiments, e.g., a solvent to be described below. The solubility may be obtained by an amount (g) of the dye dissolved in 100 g of the solvent. If the solubility of the metal complex dye is within the above range, compatibility with other components constituting the photosensitive resin composition according to some embodiments and coloring power may be secured, and precipitation of the dye may be prevented.

The solvent may include, e.g., propylene glycol monomethyl ether acetate (PGMEA), ethyl lactate (EL), ethylene glycol ethyl acetate (EGA), cyclohexanone (cyclohexanone), 3-methoxy-1-butanol, or a combination thereof.

If it has the above specific range, it may be usefully used for color filters such as LCDs and LEDs that express high luminance and high contrast ratio in a desired color coordinate.

The metal complex dye may be included in an amount of about 0.01 wt % to about 1 wt %, e.g., about 0.01 wt % to about 0.5 wt %, based on a total weight of the photosensitive resin composition. If the metal complex dye is used in the above range, high luminance and contrast ratio may be exhibited in a desired color coordinate.

If the dye and the pigment are mixed and used, they may be mixed in a weight ratio of about 0.1:99.9 to about 99.9:0.1, e.g., about 1:9 to about 9:1. If mixed in the above weight ratio ranges, chemical resistance and maximum absorption wavelength may be controlled within an appropriate range, and high luminance and contrast ratio may be exhibited in a desired color coordinate.

The colorant may be included in an amount of about 5 wt % to about 70 wt %, e.g., about 6 wt % to about 50 wt %, or about 7 wt % to about 30 wt %, based on a total amount of the photosensitive resin composition. If the colorant is included within the above ranges, a coloring effect and developability are improved.

(F) Solvent

The solvent may be a material that has compatibility with the additive, the binder resin, the photopolymerizable compound, and the photopolymerization initiator, but does not react therewith.

Examples of the solvent may include alcohols such as methanol, ethanol, and the like; ethers such as dichloroethyl ether, n-butyl ether, diisoamyl ether, methylphenyl ether, tetrahydrofuran, and the like; alkyl acetates such as ethyl acetate, butyl acetate, and the like; glycol ethers such as ethylene glycol monomethylether, ethylene glycol monoethylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol methylether acetate, propylene glycol propylether acetate, and the like; aromatic hydrocarbons such as toluene, xylene and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, butyl oxyacetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxy propionic acid alkyl esters such as 3-oxy methyl propionate, 3-oxy ethyl propionate, and the like; 3-alkoxy propionic acid alkyl esters such as 3-methoxy methyl propionate, 3-methoxy ethyl propionate, 3-ethoxy ethyl propionate, 3-ethoxy methyl propionate, and the like; 2-oxy propionic acid alkyl esters such as 2-oxy methyl propionate, 2-oxy ethyl propionate, 2-oxy propyl propionate, and the like; 2-alkoxy propionic acid alkyl esters such as 2-methoxy methyl propionate, 2-methoxy ethyl propionate, 2-ethoxy ethyl propionate, 2-ethoxy methyl propionate, and the like; 2-oxy-2-methyl propionic acid esters such 2-oxy-2-methyl methyl propionate, 2-oxy-2-methyl ethyl propionate, and the like, monooxy monocarboxylic acid alkyl esters of 2-alkoxy-2-methyl alkyl propionates such as 2-methoxy-2-methyl methyl propionate, 2-ethoxy-2-methyl ethyl propionate, and the like; esters such as 2-hydroxy ethyl propionate, 2-hydroxy-2-methyl ethyl propionate, hydroxy ethyl acetate, 2-hydroxy-3-methyl methyl butanoate, and the like; ketonate esters such as ethyl pyruvate, and the like. In an implementation, high boiling point solvent such as N-methylformamide, N,N-dimethylformamide, N-methylformanilide, N-methylacetamide, N,N-dimethylacetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, y-butyrolactone, ethylene carbonate, propylene carbonate, phenyl cellosolve acetate, and the like may be also used.

In an implementation, considering compatibility and reactivity, ketones such as cyclohexanone; glycol ethers such as ethylene glycol monoethyl ether; ethylene glycol alkyl ether acetates such as ethyl cellosolve acetate; esters such as 2-hydroxy ethyl propionate; carbitols such as diethylene glycol monomethyl ether; propylene glycol alkyl ether acetates such as propylene glycol monomethyl ether acetate and propylene glycol propyl ether acetate, and ketones such as cyclohexanone may be used.

In an implementation, the solvent may include two or more solvents having different boiling points. The “boiling point” of a liquid material is a temperature at which the vapor pressure of the liquid material becomes equal to the external pressure and starts to boil, and it changes according to the external pressure. Some embodiments address the boiling point at 1 atm.

In an implementation, the photosensitive resin composition of some embodiments may include two solvents having different boiling points, a volatilization rate and a volatilization position of the solvent may be harmoniously controlled in the process of coating the photosensitive resin composition on the substrate or the lower photosensitive resin layer, and by allowing volatilization of the solvent to occur mainly on the surface rather than under the coating, filling characteristics, surface roughness, and the like may be improved.

In an implementation, the solvent may include two or more solvents of propylene glycol monomethyl ether acetate (PGMEA), n-butyl alcohol (n-BA), and diethylene glycol methyl ethyl ether (MEDG). In an implementation, all three types of solvents may be included, and in this case, the synergistic effect may be the highest.

In an implementation, the solvent may be included in a balance amount. In an implementation, the solvent may be included in an amount of, e.g., about 30 wt % to about 60 wt %, or about 40 wt % to about 50 wt %, based on a total weight of the photosensitive resin composition. If the solvent is included within the above ranges, it is possible to obtain a coating film having excellent coatability of the photosensitive resin composition and excellent flatness.

The photosensitive resin composition may be applied to a photosensitive resin composition for a color filter of a CMOS image sensor, e.g., a photosensitive resin composition for a blue color filter of a CMOS image sensor.

(Photosensitive Resin Layer, Color Filter, and CMOS Image Sensor)

Some embodiments provide a photosensitive resin layer manufactured using the photosensitive resin composition.

Some embodiments provide a color filter manufactured using the photosensitive resin composition.

Some embodiments provide a CMOS image sensor including a color filter.

A method of manufacturing the color filter may be as follows.

The aforementioned photosensitive resin composition may be coated to form a photosensitive resin composition layer with a suitable thickness on a glass substrate using a suitable method, e.g., spin coating, roller coating, spray coating, or the like.

Subsequently, the substrate having the photosensitive resin composition layer may be irradiated by light or radiation to form a pattern for a color filter. The irradiation may be performed by using UV, an electron beam, or an X-ray as a light or radiation source. In an implementation, the UV may be irradiated, e.g., in a wavelength region of about 190 nm to about 450 nm, e.g., about 200 nm to about 400 nm. The irradiation may be performed by further using a photoresist mask. After performing the irradiation process in this way, the photosensitive resin composition layer exposed to the light source may be treated with a developing solution. Herein, a non-exposed region of the photosensitive resin composition layer may be dissolved and may form the pattern for a color filter. This process may be repeated as many times as the number of necessary colors, obtaining a color filter having a desired pattern. In an implementation, if the image pattern obtained through development in the above process is cured by reheating or irradiation an actinic ray thereinto, crack resistance, solvent resistance, and the like may be improved.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

(Preparation of Photosensitive Resin Compositions)

### Examples 1 to 9 and Comparative Examples 1 to 6

Each photosensitive resin composition was prepared by mixing the compositions shown in Tables 1 to 3.

For example, after dissolving the photopolymerization initiator in the solvent, the mixture was stirred at ambient temperature for 30 minutes, and then the binder resin was added thereto and stirred at room temperature for 60 minutes. Subsequently, the photopolymerizable compound and colorant (pigment dispersion) were added to the obtained reactants and stirred at ambient temperature for 30 minutes. Additionally, the additives were added and stirred at ambient temperature for 30 minutes. Then, each photosensitive resin composition was prepared by filtering the product twice to remove impurities.

TABLE 1
(unit: wt %)

| | | Solid | | | | | |
|---|---|---|---|---|---|---|---|
| | | content | Comparative | Comparative | Comparative | | |
| Components | Material | (wt %) | Example 1 | Example 2 | Example 3 | Example 1 | Example 2 |
| (A) Additive | A-1 | 10 | 0 | 0.05 | 0.10 | 0.15 | 0.20 |
| | A-2 | 10 | — | — | — | — | — |
| | A-3 | — | 0.10 | 0.10 | 0.10 | 0.10 | 0.10 |
| (B) Binder resin | B-1 | 38.6 | 3.73 | 3.73 | 3.73 | 3.73 | 3.73 |
| (C) Photopolymerizable | C-1 | 100 | 1.44 | 1.44 | 1.44 | 1.44 | 1.44 |
| compound | | | | | | | |
| (D) Photopolymerization | D-1 | 100 | 0.547 | 0.547 | 0.547 | 0.547 | 0.547 |
| initiator | | | | | | | |
| (E) Colorant | E-1 | 18 | 43.49 | 43.49 | 43.49 | 43.49 | 43.49 |
| (F) Solvent | F-1 | — | 23.8 | 23.8 | 23.8 | 23.8 | 23.8 |
| | F-2 | — | 26.58 | 26.58 | 26.58 | 26.58 | 26.58 |

| | | | | | | |
|---|---|---|---|---|---|---|
| Total | 100 | 100 | 100 | 100 | 100 | 100 |

TABLE 2
(unit: wt %)

| | | Solid | | | | | |
|---|---|---|---|---|---|---|---|
| | | content | | | Comparative | Comparative | Comparative |
| Components | Material | (wt %) | Example 3 | Example 4 | Example 4 | Example 5 | Example 6 |
| (A) Additive | A-1 | 10 | 0.25 | 0.3 | 0.35 | 0.40 | 1 |
| | A-2 | 10 | — | — | — | — | — |
| | A-3 | — | 0.10 | 0.10 | 0.10 | 0.10 | 0.10 |
| (B) Binder resin | B-1 | 38.6 | 3.73 | 3.73 | 3.73 | 3.73 | 3.73 |
| (C) Photopolymerizable | C-1 | 100 | 1.44 | 1.44 | 1.44 | 1.44 | 1.44 |
| compound | | | | | | | |
| (D) Photopolymerization | D-1 | 100 | 0.547 | 0.547 | 0.547 | 0.547 | 0.547 |
| initiator | | | | | | | |
| (E) Colorant | E-1 | 18 | 43.49 | 43.49 | 43.49 | 43.49 | 43.49 |
| (F) Solvent | F-1 | — | 23.8 | 23.8 | 23.8 | 23.8 | 23.8 |
| | F-2 | — | 26.58 | 26.58 | 26.58 | 26.58 | 26.58 |

| | | | | | | |
|---|---|---|---|---|---|---|
| Total | 100 | 100 | 100 | 100 | 100 | 100 |

TABLE 3
(unit: wt %)

| | | Solid | | | | | |
|---|---|---|---|---|---|---|---|
| | | content | | | | | |
| Components | Material | (wt %) | Example 5 | Example 6 | Example 7 | Example 8 | Example 9 |
| (A) Additive | A-1 | 10 | — | — | — | — | 0.15 |
| | A-2 | 10 | 0.15 | 0.20 | 0.25 | 0.3 | 0.15 |
| | A-3 | — | 0.10 | 0.10 | 0.10 | 0.10 | 0.10 |
| (B) Binder resin | B-1 | 30 | 3.73 | 3.73 | 3.73 | 3.73 | 3.73 |
| (C) Photopolymerizable | C-1 | 100 | 1.44 | 1.44 | 1.44 | 1.44 | 1.44 |
| compound | | | | | | | |
| (D) Photopolymerization | D-1 | 100 | 0.547 | 0.547 | 0.547 | 0.547 | 0.547 |
| initiator | | | | | | | |
| (E) Colorant | E-1 | | 43.49 | 43.49 | 43.49 | 43.49 | 43.49 |
| (F) Solvent | F-1 | — | 23.8 | 23.8 | 23.8 | 23.8 | 23.8 |
| | F-2 | — | 26.58 | 26.58 | 26.58 | 26.58 | 26.58 |

| | | | | | | |
|---|---|---|---|---|---|---|
| Total | 100 | 100 | 100 | 100 | 100 | 100 |

Each component used in Tables 1 to 3 was as follows.

(A) Additive
(A-1) Dilution of fluorine surfactant (product name: F-556, manufacturer: DIC Co., Ltd.) (dispersion medium: PGMEA)
(A-2) Dilution of fluorine surfactant (product name: F-553, manufacturer: DIC Co., Ltd.) (dispersion medium: PGMEA)
(A-3) Silane coupling agent (product name: KBM-503, manufacturer: Shinetsu)

(B) Binder Resin
(B-1) Dispersion of acrylic binder resin (product name: RY-92, manufacturer: Showa Denko, weight average molecular weight: 5,000 to 20,000 g/mol, acid value: 30 to 180 KOHmg/g) (solvent: PGMEA)

(C) Photopolymerizable Compound
(C-1) Dipentaerythritolhexaacrylate (DPHA, manufacturer: Nippon Kayaku Co., Ltd.)

(D) Photopolymerization Initiator
(D-1) Oxime initiator (product name: SPI-03, manufacturer: Samyang Corp.)

(E) Colorant
(E-1) Mixed pigment dispersion of B 15:6 and V 23 (solvent: PGMEA)

(F) Solvent
(F-1) Propylene glycol monomethyl ether acetate (PGMEA, boiling point: 146.4° C., manufacturer: Sigma-Aldrich Co., Ltd.)
(F-2) N-butyl alcohol (n-BA, boiling point: 117.7° C. @ 1 atm, manufacturer: Sigma Aldrich)

### Evaluation Example 1: Viscosity of Photosensitive Resin Composition

At 25° C., 4 g of each photosensitive resin composition according to Examples 1 to 9 and Comparative Examples 1 to 7 was coated, and the viscosity was evaluated using a rheometer. The evaluation results are shown in Table 4.

TABLE 4

| | | Content of | |
|---|---|---|---|
| | | leveling | |
| | | agent in | Viscosity of |
| | | photosensitive | photosensitive |
| | | resin | resin |
| | Type of leveling agent | composition | composition |
| Comparative | — | — | 1.90 cP |
| Example 1 | | | |
| Comparative | fluorine surfactant F-556 | 5 ppm | 1.87 cP |
| Example 2 | | | |
| Comparative | fluorine surfactant F-556 | 10 ppm | 1.88 cP |
| Example 3 | | | |
| Example 1 | fluorine surfactant F-556 | 15 ppm | 1.90 cP |
| Example 2 | fluorine surfactant F-556 | 20 ppm | 1.87 cP |
| Example 3 | fluorine surfactant F-556 | 25 ppm | 1.87 cP |
| Example 4 | fluorine surfactant F-556 | 30 ppm | 1.88 cP |
| Comparative | fluorine surfactant F-556 | 35 ppm | 1.87 cP |
| Example 4 | | | |
| Comparative | fluorine surfactant F-556 | 40 ppm | 1.89 cP |
| Example 5 | | | |
| Comparative | fluorine surfactant F-556 | 100 ppm | 1.85 cP |
| Example 6 | | | |
| Example 5 | fluorine surfactant F-553 | 15 ppm | 1.87 cP |
| Example 6 | fluorine surfactant F-553 | 20 ppm | 1.87 cP |
| Example 7 | fluorine surfactant F-553 | 25 ppm | 1.87 cP |
| Example 8 | fluorine surfactant F-553 | 30 ppm | 1.89 cP |
| Example 9 | fluorine surfactant | 20 ppm | 1.92 cP |
| | (mixture of F-556:F- | | |
| | 553 = 1:1 weight ratio) | | |

### Evaluation Example 2: Surface Characteristics of Color Filter

(1) Surface Roughness

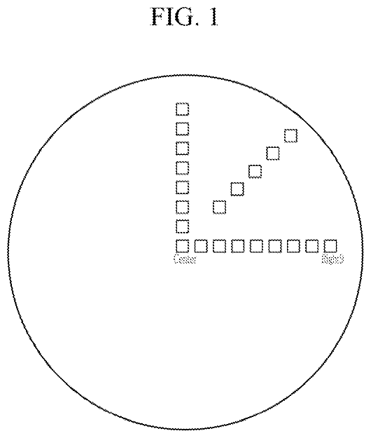

Each of the photosensitive resin compositions according to Examples 1 to 9 and Comparative Examples 1 to 6 was coated on an 8-inch Si substrate with a spin coater (Opticoat MS-A150, Mikasa Co., Ltd.), soft-baked on a hot-plate at 100° C. for 180 seconds, and exposed to light for 1,000 msec by irradiating it with an i-line stepper (NSR-2005i10C, Nikon Inc.). The exposure proceeded in a region marked as a quadrangle in FIG. 1.

The exposed substrate was developed in a 0.19% TMAH aqueous solution at ambient temperature in a spray & puddle method and then, hard-baked at 200° C. for 5 minutes. Accordingly, a 5,000 Å-thick photosensitive resin layer was formed on the Si substrate, obtaining color filter specimens.

Each of the obtained color filter specimens was taken an image of at 200 magnification with a microscope (model name: BX51, Manufacturer: Olympus Corp.). The image was shaded and then, checked with respect to surface roughness in a second quadrangle region from the right with naked eyes, giving “good” if the surface was not rough, “inferior” if the surface was rough, and “very inferior” if the surface was very rough, and the results are shown in Table 5.

(2) Surface Lattice Patterns

Each of the obtained color filter specimens was checked to have a lattice pattern visually identified with naked eyes, giving “good” if the lattice pattern was clearly identified, “inferior” if the lattice pattern was unclearly identified, and “very inferior” if the lattice pattern was not identified, and the results are shown in Table 5.

(3) Thickness

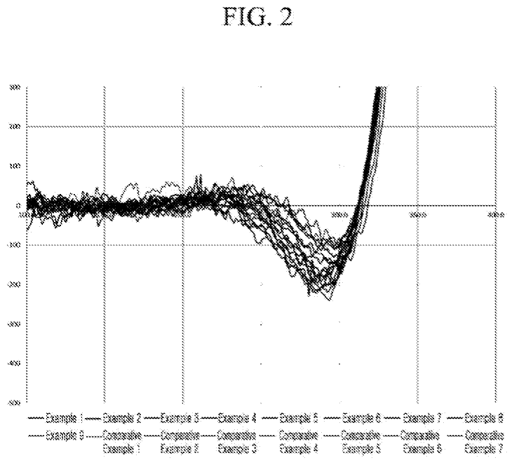

Each of the obtained color filter specimens was measured with respect to a 1,000 μm-thick profile at a scanning speed of 50 μm/s by using a thickness meter (Model name: P-16, Manufacturer: KLA Instruments), and the results are shown in FIG. 2.

TABLE 5

| | Surface roughness | Lattice pattern |
|---|---|---|
| Comparative Example 1 | very inferior | very inferior |
| Comparative Example 2 | good | very inferior |
| Comparative Example 3 | good | inferior |
| Example 1 | good | good |
| Example 2 | good | good |
| Example 3 | good | good |
| Example 4 | good | good |
| Comparative Example 4 | inferior | good |
| Comparative Example 5 | inferior | good |
| Comparative Example 6 | very inferior | good |
| Example 5 | good | good |
| Example 6 | good | good |
| Example 7 | good | good |
| Example 8 | good | good |
| Example 9 | good | good |

Comprehensively evaluating the results of Tables 4 and 5, viscosity of the photosensitive resin composition turned out to vary according to a content of the leveling agent, e.g., if the leveling agent was included in an amount of 15 ppm to 30 ppm based on a total amount of the photosensitive resin composition, surface roughness and a lattice pattern of the color filter specimens were improved.

Accordingly, if an amount of the leveling agent was optimized within a range of 15 ppm to 30 ppm based on a total amount of the photosensitive resin composition, coating uniformity of the photosensitive resin composition on the substrate or the lower photosensitive resin layer was achieved.

Furthermore, the photosensitive resin composition of some embodiments, which were represented by Examples 1 to 9, turned out to form a photosensitive resin layer and a color filter with excellent surface smoothness and thus contribute to realizing an image sensor with image quality at a predetermined level.

By way of summation and review, if a thickness distribution were to occur in the process of coating the photosensitive resin composition on a substrate or a lower photosensitive resin layer, the surface of the finally manufactured color filter could be physically rough.

One or more embodiments may provide a photosensitive resin composition coated with a uniform thickness on a substrate or a lower photosensitive resin layer.

The photosensitive resin composition of some embodiments may be coated with a uniform thickness on a substrate or a lower photosensitive resin layer by including a leveling agent in a specific content range.

Thus, the photosensitive resin layer and the color filter manufactured using the photosensitive resin composition of some embodiments may have excellent surface smoothness and may contribute to realizing image quality of the image sensor at a constant level.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive resin composition, comprising:
an additive;
a binder resin;
a photopolymerizable compound;
a photopolymerization initiator;
a colorant; and
a solvent,
wherein:
the additive includes a leveling agent, and
the leveling agent is included in an amount of about 15 ppm to about 30 ppm, based on a total amount of the photosensitive resin composition.

2. The photosensitive resin composition as claimed in claim 1, wherein the leveling agent is included in an amount of about 20 ppm to about 25 ppm, based on the total amount of the photosensitive resin composition.

3. The photosensitive resin composition as claimed in claim 1, wherein the leveling agent is a fluorine surfactant.

4. The photosensitive resin composition as claimed in claim 3, wherein the fluorine surfactant is a non-ionic fluorine surfactant.

5. The photosensitive resin composition as claimed in claim 1, wherein the additive further includes a dispersion medium.

6. The photosensitive resin composition as claimed in claim 5, wherein the leveling agent is included in an amount of about 1 wt % to about 20 wt %, based on a total weight of the additive.

7. The photosensitive resin composition as claimed in claim 1, wherein a weight ratio of the leveling agent and the colorant is about 1:700 to about 1:900.

8. The photosensitive resin composition as claimed in claim 1, wherein the additive further includes malonic acid; 3-amino-1,2-propanediol; a coupling agent that includes a vinyl group or a (meth)acryloxy group; or a radical polymerization initiator.

9. The photosensitive resin composition as claimed in claim 1, wherein the binder resin includes an acrylic binder resin, an epoxy binder resin, or a combination thereof.

10. The photosensitive resin composition as claimed in claim 1, wherein the colorant includes a blue pigment, a violet pigment, or a combination thereof.

11. The photosensitive resin composition as claimed in claim 1, wherein the solvent includes two or more solvents having different boiling points.

12. The photosensitive resin composition as claimed in claim 11, wherein the solvent includes two or more of propylene glycol monomethyl ether acetate (PGMEA), n-butyl alcohol (n-BA), and diethylene glycol methyl ethyl ether (MEDG).

13. The photosensitive resin composition as claimed in claim 1, wherein the photosensitive resin composition includes:
about 15 ppm to about 30 ppm of the additive;
about 1 wt % to about 20 wt % of the binder resin;
about 1 wt % to about 20 wt % of the photopolymerizable compound;
about 0.1 wt % to about 5 wt % of the photopolymerization initiator;
about 5 wt % to about 70 wt % of the colorant; and
the solvent, all amounts being based on a total weight of the photosensitive resin composition.

14. The photosensitive resin composition as claimed in claim 1, wherein the photosensitive resin composition has a viscosity of about 1.5 cP to about 3.8 cP at 25° C.

15. A photosensitive resin layer manufactured using the photosensitive resin composition as claimed in claim 1.

16. A color filter including a photosensitive resin layer as claimed in claim 15.

17. A CMOS image sensor comprising the color filter as claimed in claim 16.
